(19) United States
(12) Patent Application Publication
(10) Pub. No.: US 2021/0242047 A1
(43) Pub. Date: Aug. 5, 2021

(54) CERAMIC HEATER AND MANUFACTURING METHOD FOR SAME

(71) Applicant: NGK INSULATORS, LTD., Nagoya-City (JP)

(72) Inventors: Noboru KAJIHARA, Santa Clara, CA (US); Shuichiro MOTOYAMA, Nagoya-City (JP)

(73) Assignee: NGK INSULATORS, LTD., Nagoya-City (JP)

(21) Appl. No.: 17/159,386

(22) Filed: Jan. 27, 2021

(30) Foreign Application Priority Data
Feb. 3, 2020 (JP) 2020-016114

(51) Int. Cl. H01L 21/67; H05B 3/28

(52) U.S. Cl. CPC H01L 21/67103; H05B 2203/017; H05B 3/283

(57) ABSTRACT

A ceramic heater includes a ceramic plate having a surface that serves as a wafer placement surface, resistance heating elements and that are embedded in the ceramic plate, a tubular shaft that supports the ceramic plate from a rear surface of the ceramic plate, a recess that is formed in a within-shaft region of the rear surface of the ceramic plate, the within-shaft region being surrounded by the tubular shaft, and that has a size equal to a size of the within-shaft region, an elongate hole that extends from an opening formed in a side surface of the recess up to a predetermined terminal end position in an outer peripheral portion of the ceramic plate, and associated parts (such as terminals) that are disposed in the within-shaft region of the rear surface of the ceramic plate.

### BACKGROUND OF THE INVENTION

### 1. Field of the Invention

The present invention relates to a ceramic heater and a manufacturing method for the ceramic heater.

### 2. Description of the Related Art

As one type of ceramic heater, there has hitherto been known the so-called two-zone heater in which resistance heating elements are embedded independently of each other in an inner peripheral side and an outer peripheral side of a disk-shaped ceramic plate having a wafer placement surface. For example, Patent Literature (PTL) 1 discloses a ceramic heater 410 illustrated in FIGS. 11 and 12. In the ceramic heater 410, a temperature in an outer peripheral side of a ceramic plate 420 is measured by an outer-peripheral-side thermocouple 450. A thermocouple guide 432 extends straight through the inside of a tubular shaft 440 from a lower side toward an upper side and is then bent in an arch shape to turn 90°. The thermocouple guide 432 is attached to a slit 426a that is formed in a region of a rear surface of the ceramic plate 420, the region being surrounded by the tubular shaft 440. The slit 426a serves as an inlet portion of a thermocouple passage 426. The outer-peripheral-side thermocouple 450 is inserted into a tube of the thermocouple guide 432 and extends up to a terminal end position of the thermocouple passage 426.

### CITATION LIST

### Patent Literature

PTL 1: WO 2012/039453 A1 (FIG. 11)

### SUMMARY OF THE INVENTION

However, associated parts, such as heater terminals, are arranged in the region of the rear surface of the ceramic plate 420, that region being surrounded by the tubular shaft 440. Accordingly, the arrangement of those associated parts is restricted by the presence of the slit 426a in some cases.

The present invention has been made with intent to solve the above-mentioned problem, and a main object of the present invention is to increase a degree of freedom in arrangement of associated parts.

A ceramic heater according to the present invention includes:

a ceramic plate having a surface that serves as a wafer placement surface;

a resistance heating element that is embedded in the ceramic plate;

a tubular shaft that supports the ceramic plate from a rear surface of the ceramic plate;

a recess that is formed in a within-shaft region of the rear surface of the ceramic plate, the within-shaft region being surrounded by the tubular shaft;

an elongate hole that extends from an opening formed in a side surface of the recess up to a predetermined terminal end position in an outer peripheral portion of the ceramic plate; and

associated parts that are disposed in the within-shaft region of the rear surface of the ceramic plate and that include terminals of the resistance heating element.

According to the above-described ceramic heater, the recess is formed in the within-shaft region of the rear surface of the ceramic plate, that within-shaft region being surrounded by the tubular shaft. The elongate hole is formed to extend from the opening formed in the side surface of the recess up to the predetermined terminal end position in the outer peripheral portion of the ceramic plate, and the associated parts are disposed in the within-shaft region of the rear surface of the ceramic plate. An entrance of the elongate hole is not a slit formed in the within-shaft region unlike the related art, but the opening formed in the side surface of the recess. Therefore, the within-shaft region is not restricted by the presence of the slit. As a result, a degree of freedom in arrangement of the associated parts is increased.

In the ceramic heater according to the present invention, the recess may have a size equal to a size of the within-shaft region. With this feature, since an area of a bottom surface of the recess can be increased, the bottom surface of the recess can be effectively utilized. Here, the wording “the recess has a size equal to a size of the within-shaft region” includes not only the case in which an outer contour of the recess and an outer contour of the within-shaft region exactly match each other, but also the case in which there is a small difference between the outer contour of the recess and the outer contour of the within-shaft region.

In the ceramic heater according to the present invention, the resistance heating element may include an inner-peripheral-side resistance heating element embedded in an inner peripheral portion of the ceramic plate and an outer-peripheral-side resistance heating element embedded in an outer peripheral portion of the ceramic plate, and the associated parts may include a pair of terminals of the inner-peripheral-side resistance heating element and a pair of terminals of the outer-peripheral-side resistance heating element. With this feature, a degree of freedom in arrangement of the pairs of the terminals of the inner-peripheral-side and outer-peripheral-side resistance heating elements is increased.

In the ceramic heater according to the present invention, the ceramic plate may include a body portion having a disk shape, having the wafer placement surface, and including the resistance heating element embedded therein, and an annular portion being concentric to the body portion and bonded to a rear surface of the body portion, the recess may be an inner center space of the annular portion, and the elongate hole may be formed by an elongate groove formed in a surface of the annular portion and by the body portion. With this feature, the recess and the elongate hole can be relatively easily formed.

In the ceramic heater according to the present invention, the ceramic plate may include a body portion having a disk shape, having the wafer placement surface, and including the resistance heating element embedded therein, and an annular portion being concentric to the body portion and bonded to a rear surface of the body portion, the recess may include an inner center space of the annular portion and a circular hollow formed in a region of the rear surface of the body portion, the region being opposite to the inner center space of the annular portion, and the elongate hole may be formed by an elongate groove formed in the rear surface of the body portion to be communicated with the circular hollow and by the annular portion. With this feature, the recess and the elongate hole can be relatively easily formed. Furthermore, since the elongate groove is formed in the body portion, a thickness of the annular portion can be reduced.

In the ceramic heater according to the present invention, the side surface of the recess may be located at a position visually recognizable from an end portion side of the tubular shaft. With this feature, it is easier to set other members (for example, a thermocouple and a thermocouple guide) into the opening of the elongate hole, that opening being formed in the side surface of the recess.

In the ceramic heater according to the present invention, the elongate hole may be a thermocouple-insertion elongate hole into which a thermocouple is to be inserted. With this feature, a temperature at the predetermined terminal end position of the elongate hole can be measured by inserting the thermocouple into the elongate hole.

The ceramic heater according to the present invention may further include the thermocouple having been inserted into the elongate hole. With this feature, the temperature at the predetermined terminal end position of the elongate hole can be measured by the thermocouple. In such a case, the thermocouple preferably has a shape following an inner wall of the tubular shaft in an inner space of the tubular shaft. With this feature, even when the associated parts are arranged near the center of the within-shaft region and various members connected to the associated parts are arranged in the inner space of the tubular shaft, those associated parts and various members are less likely to interfere with the thermocouple.

The ceramic heater according to the present invention may further include a thermocouple guide that guides a tip end of the thermocouple to pass through the opening of the elongate hole, and the thermocouple may be inserted into the elongate hole while being guided by the thermocouple guide. With this feature, the thermocouple can easily be inserted into the elongate hole with the aid of the thermocouple guide. In such a case, the thermocouple guide preferably has a shape following an inner wall of the tubular shaft. With this feature, even when the associated parts are arranged near the center of the within-shaft region and various members connected to the associated parts are arranged in the inner space of the tubular shaft, those associated parts and various members are less likely to interfere with the thermocouple guide. Furthermore, the elongate hole may include a large-diameter portion and a small-diameter portion, the large-diameter portion may be a portion having a predetermined length from the opening, the small-diameter portion may be a portion of the elongate hole except for the large-diameter portion, the large-diameter portion may have a diameter allowing the tip end of the thermocouple guide to be inserted therethrough, and a diameter of the small-diameter portion may be smaller than the diameter of the large-diameter portion and allows the thermocouple to be inserted therethrough. With this feature, the influence of the elongate hole on uniformity in heating can be reduced by increasing the diameter of only the large-diameter portion into which the tip end of the thermocouple guide is fitted, and by reducing the diameter of the other portion of the elongate hole (namely, of the small-diameter portion).

A manufacturing method for a ceramic heater according to the present invention includes steps of:

(a) obtaining a ceramic plate by preparing a circular plate in which a resistance heating element is embedded and an annular plate having the same outer diameter as the circular plate, by forming, on one surface of the annular plate, an elongate groove that extends from a center hole to an outer peripheral portion of the annular plate, and by bonding the circular plate to a surface of the annular plate on which the elongate groove has been formed;

(b) bonding a tubular shaft to a region of a rear surface of the ceramic plate around a recess that is formed by the center hole of the annular plate and the circular plate;

(c) boring a bottom surface of the recess in the ceramic plate to make the resistance heating element exposed at the bottom surface of the recess;

(d) bonding power feeder rods to the resistance heating element that has been exposed at the bottom surface of the recess; and

(e) inserting, with the aid of the thermocouple guide, a thermocouple into an elongate hole that is formed by the elongate groove in the annular plate and the circular plate.

According to the above-described manufacturing method, the ceramic heater including the thermocouple can easily be manufactured.

### BRIEF DESCRIPTION OF THE DRAWINGS

FIG. 1 is a perspective view of a ceramic heater 10.

FIG. 2 is a sectional view (vertical sectional view) taken along A-A in FIG. 1.

FIG. 3 is a sectional view taken along B-B in FIG. 1.

FIG. 4 is an enlarged view of principal part in FIG. 3.

FIG. 5 is an enlarged view of principal part in a modification of the ceramic heater 10.

FIG. 6 is a vertical sectional view of a modification of the ceramic heater 10.

FIG. 7 is a vertical sectional view of a modification of the ceramic heater 10.

FIG. 8 is a vertical sectional view of a modification of the ceramic heater 10.

FIG. 9 is an enlarged view of principal part in a modification of the ceramic heater 10.

FIG. 10 is a vertical sectional view of principal part in a modification of the ceramic heater 10.

FIG. 11 is a vertical sectional view of a related-art ceramic heater.

FIG. 12 is a sectional view taken along C-C in FIG. 10.

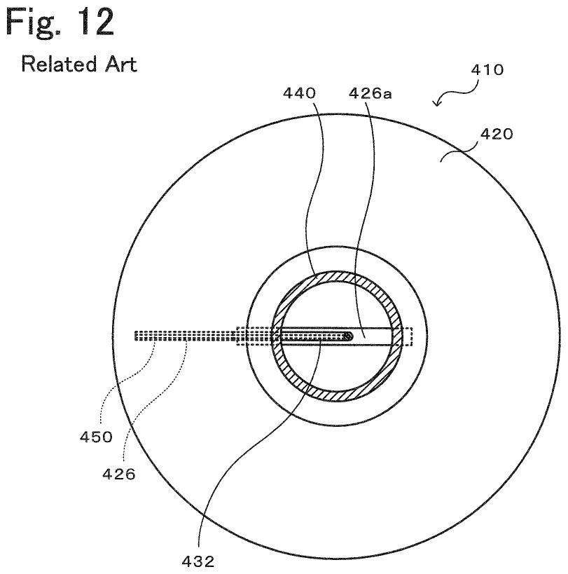

### DETAILED DESCRIPTION OF THE INVENTION

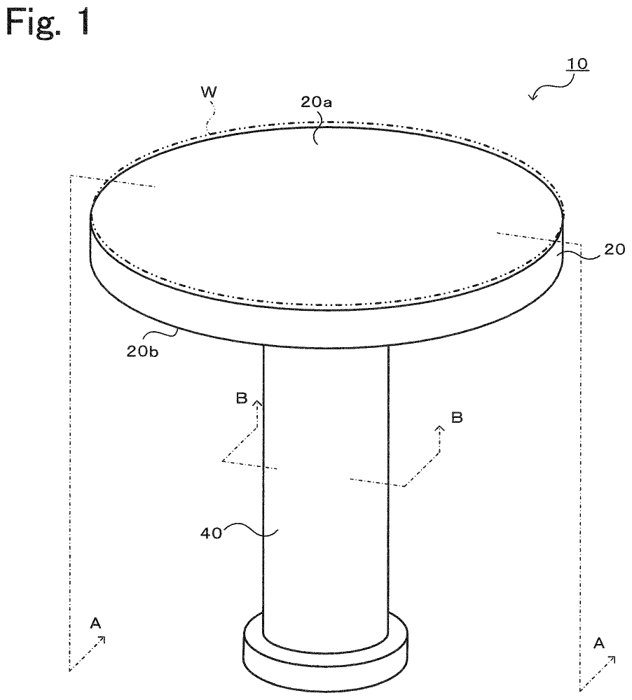

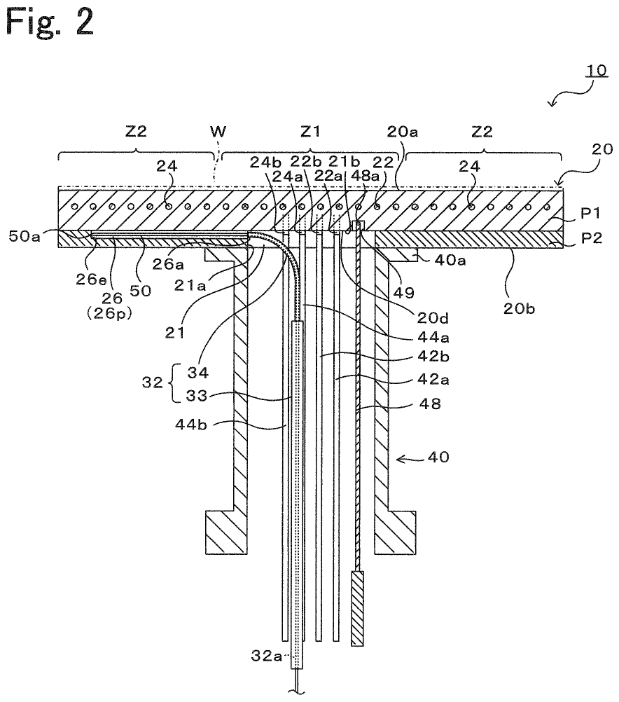

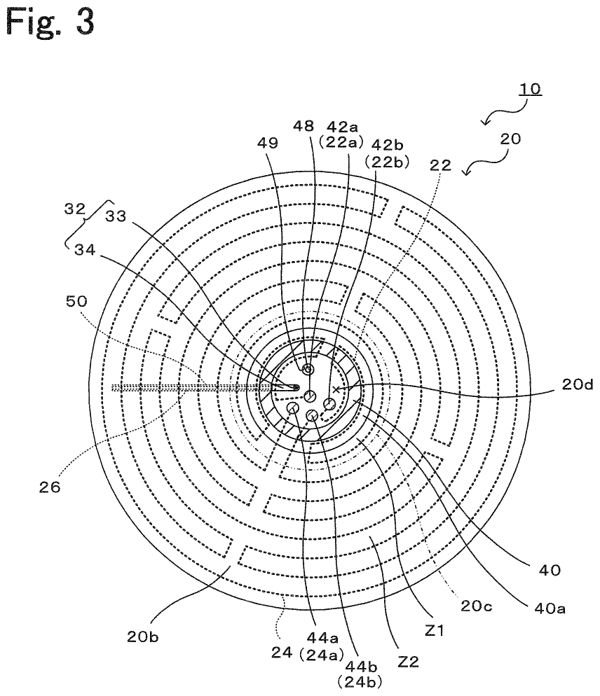

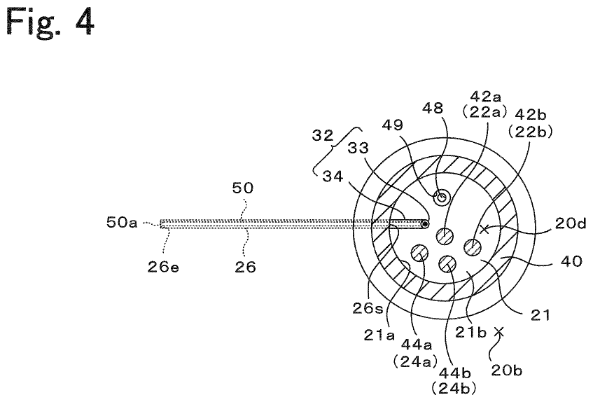

Preferred embodiments of the present invention will be described below with reference to the drawings. FIG. 1 is a perspective view of a ceramic heater 10, FIG. 2 is a sectional view taken along A-A in FIG. 1, FIG. 3 is a sectional view taken along B-B in FIG. 1, and FIG. 4 is an enlarged view of principal part in FIG. 3.

The ceramic heater 10 is used to heat a wafer W on which processing, such as etching or CVD, is to be performed, and is installed within a vacuum chamber (not illustrated). The ceramic heater 10 includes a disk-shaped ceramic plate 20 having a wafer placement surface 20a, and a tubular shaft 40 that is bonded to a surface (rear surface) 20b of the ceramic plate 20 opposite to the wafer placement surface 20a.

The ceramic plate 20 is a disk-shaped plate made of a ceramic material represented by aluminum nitride or alumina. The diameter of the ceramic plate 20 is not limited to a particular value and may be about 300 mm, for example. The ceramic plate 20 is divided into an inner-peripheral-side zone Z1 of a small circular shape and an outer-peripheral-side zone Z2 of an annular shape by a virtual boundary 20c (see FIG. 3) concentric to the ceramic plate 20. An inner-peripheral-side resistance heating element 22 is embedded in the inner-peripheral-side zone Z1 of the ceramic plate 20, and an outer-peripheral-side resistance heating element 24 is embedded in the outer-peripheral-side zone Z2. The resistance heating elements 22 and 24 are each constituted by a coil containing, as a main component, molybdenum, tungsten, or those carbide, for example. As illustrated in FIG. 2, the ceramic plate 20 is fabricated by surface-bonding, to a rear surface of a circular plate P1 in which the inner-peripheral-side and outer-peripheral-side resistance heating elements 22 and 24 are embedded, an annular plate P2 thinner than the circular plate P1. The annular plate P2 is disposed concentric to the circular plate P1 and has the same outer diameter as the circular plate P1.

The tubular shaft 40 supports the ceramic plate 20 from the rear surface 20b of the ceramic plate 20 and is made of ceramic, such as aluminum nitride or alumina, like the ceramic plate 20. A flange portion 40a at an upper end of the tubular shaft 40 is bonded to the rear surface 20b of the ceramic plate 20. The tubular shaft 40 is concentric to the ceramic plate 20 when viewed from a lower end side of the tubular shaft 40.

As illustrated in FIG. 3, the inner-peripheral-side resistance heating element 22 is formed such that it starts from one of a pair of terminals 22a and 22b and reaches the other of the pair of terminals 22a and 22b after being wired in a one-stroke pattern over substantially the entirety of the inner-peripheral-side zone Z1 while being folded at a plurality of turn-around points. The pair of terminals 22a and 22b are disposed in a within-shaft region 200d (that is defined as a region of the rear surface 20b of the ceramic plate 20, the region locating within the tubular shaft 40). Power feeder rods 42a and 42b each made of a metal (for example, Ni) are bonded respectively to the pair of terminals 22a and 22b.

As illustrated in FIG. 3, the outer-peripheral-side resistance heating element 24 is formed such that it starts from one of a pair of terminals 24a and 24b and reaches the other of the pair of terminals 24a and 24b after being wired in a one-stroke pattern over substantially the entirety of the outer-peripheral-side zone Z2 while being folded at a plurality of turn-around points. The pair of terminals 24a and 24b are disposed in the within-shaft region 20d of the rear surface 20b of the ceramic plate 20. Power feeder rods 44a and 44b each made of a metal (for example, Ni) are bonded respectively to the pair of terminals 24a and 24b.

Inside the ceramic plate 20, as illustrated in FIG. 2, an elongate hole 26 into which an outer-peripheral-side thermocouple 50 is to be inserted is formed parallel to the wafer placement surface 20a. A recess 21 is formed in the within-shaft region 20d of the rear surface 20b of the ceramic plate 20. The recess 21 is an inner center space of the annular plate P2 and has a size substantially equal to that of the within-shaft region 20d. In this embodiment, the inner diameter of the recess 21 and the inner diameter of the tubular shaft 40 are equal to each other, or the difference between both the inner diameters is very small. Here, because the ceramic plate 20 and the tubular shaft 40 are bonded by pressing the flange portion 40a of the tubular shaft 40, the recess 21 may be formed to span up to a region that is positioned outside an outer wall of the tubular shaft 40. The elongate hole 26 extends from an opening 26a formed in a side surface 21a of the recess 21 to a predetermined terminal end position 26e in an outer peripheral portion of the ceramic plate 20. In this embodiment, the elongate hole 26 is formed by covering an elongate groove 26p formed on a surface of the annular plate P2 with the circular plate P1. The side surface 21a of the recess 21 is located at a position visually recognizable from the lower end side of the tubular shaft 40.

The thermocouple guide 32 is a tubular member made of a metal (for example, stainless) and having a guide hole 32a. The thermocouple guide 32 includes a vertical portion 33 extending in a vertical direction with respect to the wafer placement surface 20a, and a curved portion 34 extending while turning from the vertical direction to a horizontal direction. An outer diameter of the vertical portion 33 is greater than that of the curved portion 34, but an inner diameter of the vertical portion 33 is the same as that of the curved portion 34. Alternatively, the outer diameter of the vertical portion 33 may be set to be the same as that of the curved portion 34. A curvature radius R of the curved portion 34 is not limited to a particular value and may be about 30 mm, for example. The outer-peripheral-side thermocouple 50 is inserted through the guide hole 32a of the thermocouple guide 32. A tip end of the curved portion 34 is bonded or joined to the side surface 21a of the recess 21 to establish communication between the guide hole 32a of the thermocouple guide 32 and the opening 26a of the elongate hole 26. However, the tip end of the curved portion 34 may be just placed without being bonded or joined. The outer-peripheral-side thermocouple 50 is arranged such that it is inserted from a lower end of the guide hole 32a of the thermocouple guide 32 bonded or joined to the side surface 21a of the recess 21 and advances into the elongate hole 26 through the opening 26a of the elongate hole 26 while being guided by the thermocouple guide 32, and that a temperature measurement portion 50a comes into contact with the terminal end position 26e.

Inside the tubular shaft 40, as illustrated in FIG. 2, there are arranged not only the thermocouple guide 32, but also the power feeder rods 42a and 42b connected respectively to the pair of terminals 22a and 22b of the inner-peripheral-side resistance heating element 22, and the power feeder rods 44a and 44b connected respectively to the pair of terminals 24a and 24b of the outer-peripheral-side resistance heating element 24. In addition, an inner-peripheral-side thermocouple 48 for measuring a temperature near the center of the ceramic plate 20 and the outer-peripheral-side thermocouple 50 for measuring a temperature near the outer periphery of the ceramic plate 20 are also arranged inside the tubular shaft 40. The inner-peripheral-side thermocouple 48 is inserted into a bottomed hole 49 formed in the within-shaft region 20d of the rear surface 20b of the ceramic plate 20, and a temperature measurement portion 48a at a tip end of the inner-peripheral-side thermocouple 48 is held in contact with the ceramic plate 20. The bottomed hole 49 is formed at a position not interfering with the terminals 22a, 22b, 24a and 24b. The outer-peripheral-side thermocouple 50 is a sheathed thermocouple and is arranged to pass through the guide hole 32a of the thermocouple guide 32 and the elongate hole 26. The temperature measurement portion 50a at a tip end of the outer-peripheral-side thermocouple 50 passes through the elongate hole 26 and reaches the terminal end position 26e.

An example of manufacturing of the ceramic heater 10 will be described below. First, the circular plate P1 in which the inner-peripheral-side and outer-peripheral-side resistance heating elements 22 and 24 are embedded and the annular plate P2 having the same outer diameter as the circular plate P1 are prepared. Then, the ceramic plate 20 is obtained by forming, on one surface of the annular plate P2, the elongate groove 26p that extends from a center hole to an outer peripheral portion of the annular plate P2, and by bonding the rear surface of the circular plate P1 and the one surface of the annular plate P2 on which the elongate groove 26p has been formed. On that occasion, the recess 21 is formed by the center hole of the annular plate P2 and the rear surface of the circular plate P1. Furthermore, the elongate hole 26 is formed by the elongate groove 26p of the annular plate P2 and the rear surface of the circular plate P1. Then, the tubular shaft 40 is bonded to a region of the rear surface of the ceramic plate 20 around the recess 21. Then, the inner-peripheral-side and outer-peripheral-side resistance heating elements 22 and 24 are exposed at a bottom surface 21b of the recess 21 by boring the bottom surface 21b of the recess 21 of the ceramic plate 20. Here, because the terminals 22a, 22b, 24a and 24b of the inner-peripheral-side and outer-peripheral-side resistance heating elements 22 and 24 are embedded in the circular plate P1, the terminals 22a, 22b, 24a and 24b are exposed at the bottom surface 21b of the recess 21. Then, the power feeder rods 42a, 42b, 44a and 44b are bonded respectively to the terminals 22a, 22b, 24a and 24b that have been exposed at the bottom surface 21b of the recess 21. Then, the outer-peripheral-side thermocouple 50 is inserted into the elongate hole 26 with the aid of the thermocouple guide 32. Through the above-described steps, the ceramic heater 10 including the outer-peripheral-side thermocouple 50 can be obtained.

An example of use of the ceramic heater 10 will be described below. First, the ceramic heater 10 is installed within a vacuum chamber (not illustrated), and the wafer W is placed on the wafer placement surface 20a of the ceramic heater 10. Then, electric power supplied to the inner-peripheral-side resistance heating element 22 is adjusted such that the temperature detected by the inner-peripheral-side thermocouple 48 is kept at a predetermined inner-peripheral-side target temperature. Furthermore, electric power supplied to the outer-peripheral-side resistance heating element 24 is adjusted such that the temperature detected by the outer-peripheral-side thermocouple 50 is kept at a predetermined outer-peripheral-side target temperature. Thus the temperature of the wafer W is controlled to be kept at a desired temperature. Thereafter, the interior of the vacuum chamber is evacuated to create a vacuum atmosphere or a pressure reduced atmosphere, plasma is generated inside the vacuum chamber, and CVD film formation or etching is performed on the wafer W by utilizing the generated plasma.

In the above-described ceramic heater 10 according to this embodiment, the recess 21 is formed in the within-shaft region 20d of the rear surface 20b of the ceramic plate 20. The elongate hole 26 is formed to extend from the opening 26a formed in the side surface 21a of the recess 21 up to the terminal end position 26e, and the terminals 22a, 22b, 24a and 24b and the bottomed hole 49, namely associated parts, are disposed in the within-shaft region 20d. An entrance of the elongate hole 26 is not a slit formed in the within-shaft region 20d unlike the related art, but the opening 26a formed in the side surface 21a of the recess 21. Therefore, the within-shaft region 20d is not restricted by the presence of the slit. As a result, a degree of freedom in arrangement of the associated parts is increased.

Furthermore, since the recess 21 has the size substantially equal to that of the within-shaft region 20d and has a larger area, the bottom surface 21b of the recess 21 can be effectively utilized.

Moreover, the ceramic plate 20 is fabricated by bonding the annular plate P2 to the rear surface of the circular plate P1, the recess 21 is the inner center space of the annular plate P2, and the elongate hole 26 is formed by the elongate groove 26p formed on the surface of the annular plate P2 and by the circular plate P1. Accordingly, the recess 21 and the elongate hole 26 can be relatively easily formed.

Since the side surface 21a of the recess 21 is located at the position visually recognizable from the lower end side of the tubular shaft 40, it is easier to set the thermocouple guide 32 into the opening 26a of the elongate hole 26, the opening 26a being formed in the side surface 21a of the recess 21.

In addition, since the outer-peripheral-side thermocouple 50 is inserted into the elongate hole 26 and the temperature measurement portion 50a is brought into contact with the terminal end position 26e of the elongate hole 26, a temperature at the terminal end position 26e can be accurately measured.

Note that it is apparent that the present invention is in no way limited to the embodiments described above, and the present invention can be carried out in a variety of ways within the technical scope of the present invention.

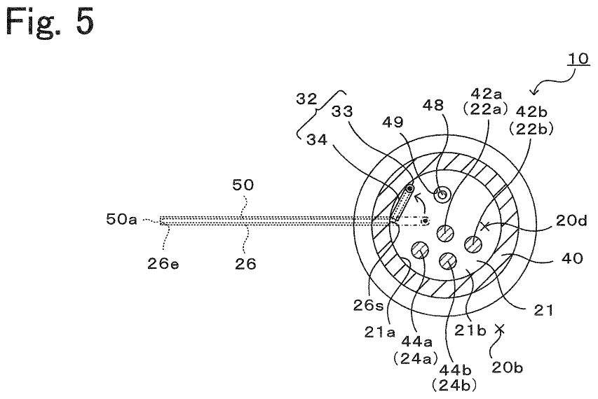

For example, in the above-described embodiment, as illustrated in FIG. 5, the thermocouple guide 32 may have a shape bent to extend along an inner wall of the tubular shaft 40. In FIG. 5, the same components as those in the above-described embodiment are denoted by the same signs. In the case of FIG. 5, even when the associated parts (such as the terminals 22a, 22b, 24a and 24b) are arranged near the center of the within-shaft region 20d and various members (such as the power feeder rods 42a, 42b, 44a and 44b) connected to the associated parts are arranged in an inner space of the tubular shaft 40, those associated parts and various members are less likely to interfere with the thermocouple guide 32.

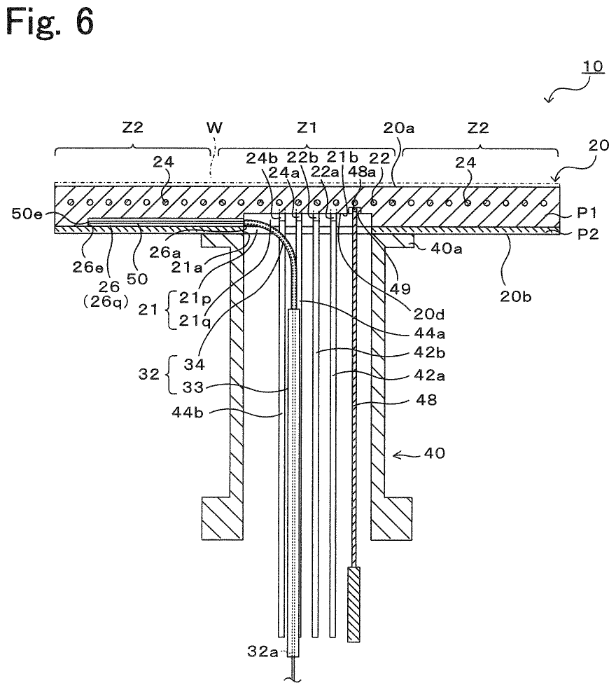

While, in the above-described embodiment, the recess 21 is the inner center space of the annular plate P2 and the elongate hole 26 is formed by the elongate groove 26p formed on the surface of the annular plate P2 and by the circular plate P1, the present invention is not always limited to such a case. For example, as illustrated in FIG. 6, the recess 21 may be constituted by an inner center space 21p of the annular plate P2 and a circular hollow 21q formed in a region of the rear surface of the circular plate P1, the region being opposite to the inner center space 21p of the annular plate P2, and the elongate hole 26 may be formed by an elongate groove 26q formed in the rear surface of the circular plate P1 to be communicated with the circular hollow 21q and by the annular plate P2. In FIG. 6, the same components as those in the above-described embodiment are denoted by the same signs. In the case of FIG. 6, the recess 21 and the elongate hole 26 can be relatively easily formed. Furthermore, since the elongate groove 26q is formed in the circular plate P1, a thickness of the annular plate P2 can be reduced.

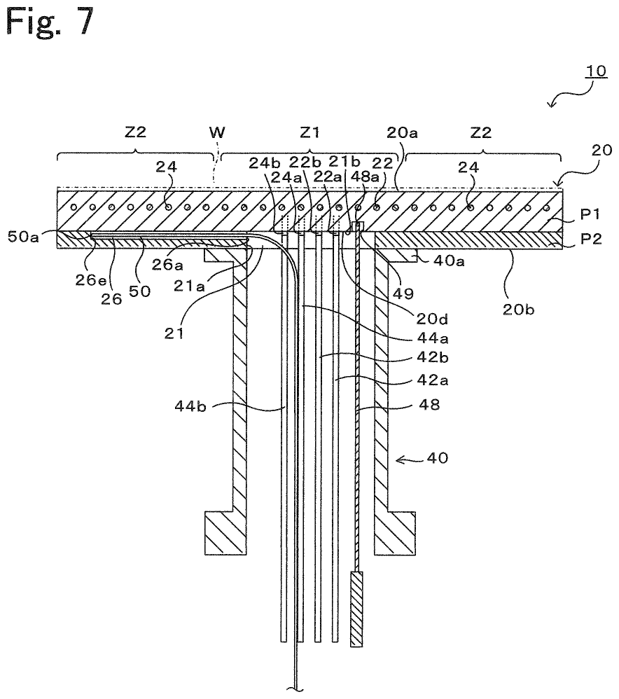

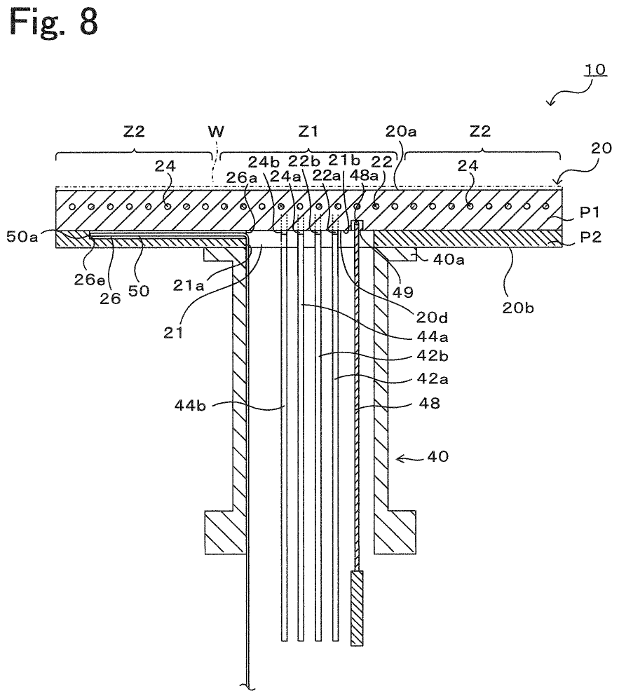

In the above-described embodiment, the thermocouple guide 32 remains attached to the side surface 21a of the recess 21 even after the outer-peripheral-side thermocouple 50 has been inserted through the elongate hole 26 with the aid of the thermocouple guide 32. However, the thermocouple guide 32 may be detached from the side surface 21a of the recess 21 after inserting the outer-peripheral-side thermocouple 50 through the elongate hole 26 with the aid of the thermocouple guide 32. The state after removing the thermocouple guide 32 is illustrated in FIG. 7. In such a case, as illustrated in FIG. 8, the outer-peripheral-side thermocouple 50 may be bent into a shape extending along the inner wall of the tubular shaft 40 in the inner space of the tubular shaft 40. With that arrangement, even when the associated parts (such as the terminals 22a, 22b, 24a and 24b) are arranged near the center of the within-shaft region 20d and various members (such as the power feeder rods 42a, 42b, 44a and 44b) connected to the associated parts are arranged in the inner space of the tubular shaft 40, those associated parts and various members are less likely to interfere with the thermocouple guide 32. In FIGS. 7 and 8, the same components as those in the above-described embodiment are denoted by the same signs.

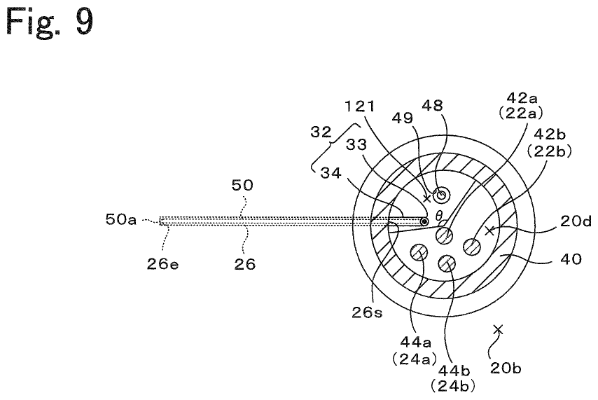

While, in the above-described embodiment, the recess 21 has the size substantially equal to that of the within-shaft region 20d, the recess 21 may be a fan-shaped groove (with a central angle θ of 90° or more, for example) including part of an outer peripheral edge of the within-shaft region 20d, like a recess 121 illustrated in FIG. 9.

While, in the above-described embodiment, the resistance heating elements 22 and 24 are each in the form of a coil, the shape of each resistance heating element is not always limited to the coil. In another example, the resistance heating element may be a print pattern or may have a ribbon-like or mesh-like shape.

In the above-described embodiment, the ceramic plate 20 may incorporate an electrostatic electrode and/or an RF electrode in addition to the resistance heating elements 22 and 24.

While the so-called two-zone heater has been described, by way of example, in the above embodiment, the present invention is not always limited to the two-zone heater. In another example, the inner-peripheral-side zone Z1 may be divided into a plurality of inner-peripheral-side small zones, and the resistance heating element may be wired in a one-stroke pattern for each of the inner-peripheral-side small zones. Furthermore, the outer-peripheral-side zone Z2 may be divided into a plurality of outer-peripheral-side small zones, and the resistance heating element may be wired in a one-stroke pattern for each of the outer-peripheral-side small zones. The outer-peripheral-side small zone may have, for example, an annular shape or a fan-like shape.

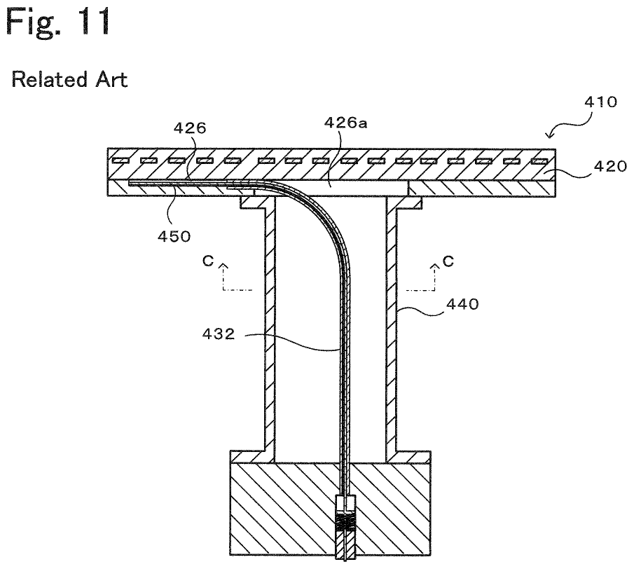

In the above-described embodiment, since the elongate hole 26 is disposed in continuation with the side surface 21a of the recess 21, the slit 426a needs not to be formed in the region of the rear surface of the ceramic plate 420, that region being surrounded by the tubular shaft 440, unlike the related art (see FIG. 11). It is hence easy to form the plurality of elongate holes 26. As a result, a temperature distribution in a circumferential direction can also easily be measured.

In the above-described embodiment, when the elongate hole 26 is formed as a passage having a cross-section of a substantially rectangular shape, the boundary between one surface and another adjacent surface within the passage (for example, the boundary between a bottom surface and a side surface) is preferably formed to define a chamfered surface or a rounded surface to be free from edges.

In the above-described embodiment, an outer diameter d of the outer-peripheral-side thermocouple 50 is preferably 0.5 mm or more and 2 mm or less. If the outer diameter d is less than 0.5 mm, the outer-peripheral-side thermocouple 50 is likely to bend when it is inserted into the thermocouple passage 26, and a difficulty arises in inserting the outer-peripheral-side thermocouple 50 up to the terminal end position 26e or the intermediate position 26m. If the outer diameter d is more than 2 mm, the outer-peripheral-side thermocouple 50 has no flexibility, and a difficulty also arises in inserting the outer-peripheral-side thermocouple 50 up to the terminal end position 26e or the intermediate position 26m.

In the above-described embodiment, when the temperature measurement portion 50a of the outer-peripheral-side thermocouple 50 has a convex surface, the elongate hole 26 may be formed to have a concave surface in part of a terminal end surface of the elongate hole 26 (part of a vertical wall at the terminal end position 26e), the part coming into contact with the temperature measurement portion 50a. In this case, since the temperature measurement portion 50a of the outer-peripheral-side thermocouple 50 is brought into surface contact or nearly surface contact with the concave surface, the accuracy of the temperature measurement can be improved.

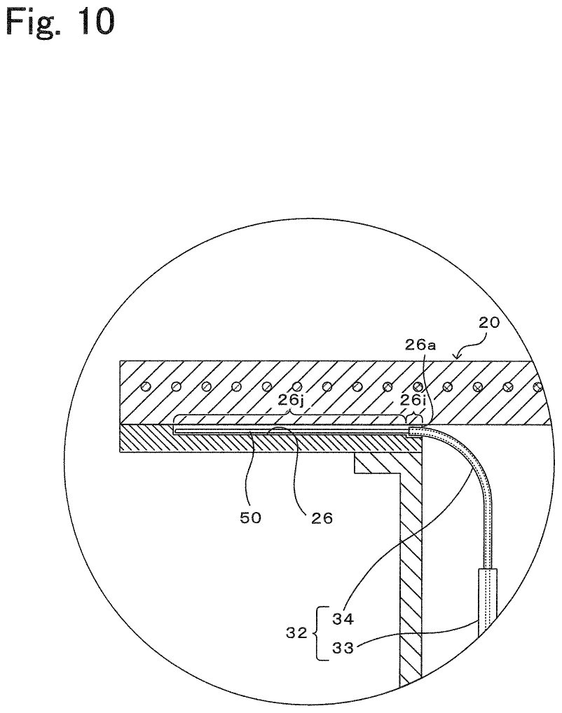

In the above embodiment, the elongate hole 26 may include a large-diameter portion 26i and a small-diameter portion 26j as illustrated in FIG. 10. The large-diameter portion 26i is a portion having a predetermined length from the opening 26a of the elongate hole 26, and the small-diameter portion 26j is a portion of the elongate hole 26 except for the large-diameter portion 26i. The large-diameter portion 26i has a diameter allowing the tip end of the thermocouple guide 32 (the tip end of the curved portion 34) to be inserted therethrough. Therefore, the tip end of the thermocouple guide 32 can be inserted into the large-diameter portion 26i and can be fixed in place. A diameter of the small-diameter portion 26j is smaller than that of the large-diameter portion 26i and allows the outer-peripheral-side thermocouple 50 thinner than the thermocouple guide 32 to be inserted therethrough. The influence of the elongate hole 26 on uniformity in heating can be reduced by, as described above, increasing the diameter of only the large-diameter portion 26i into which the tip end of the thermocouple guide 32 is fitted, and by reducing the diameter of the other portion of the elongate hole 26 (namely, of the small-diameter portion 26j).

The application claims priority to Japanese Patent Application No. 2020-016114 filed in the Japan Patent Office on Feb. 3, 2020, the entire contents of which are incorporated herein by reference.

What is claimed is:

1. A ceramic heater comprising:
a ceramic plate having a surface that serves as a wafer placement surface;
a resistance heating element that is embedded in the ceramic plate;
a tubular shaft that supports the ceramic plate from a rear surface of the ceramic plate;
a recess that is formed in a within-shaft region of the rear surface of the ceramic plate, the within-shaft region being surrounded by the tubular shaft;
an elongate hole that extends from an opening formed in a side surface of the recess up to a predetermined terminal end position in an outer peripheral portion of the ceramic plate; and
associated parts that are disposed in the within-shaft region of the rear surface of the ceramic plate and that include terminals of the resistance heating element.

2. The ceramic heater according to claim 1, wherein the recess has a size equal to a size of the within-shaft region.

3. The ceramic heater according to claim 1, wherein the resistance heating element includes an inner-peripheral-side resistance heating element embedded in an inner peripheral portion of the ceramic plate and an outer-peripheral-side resistance heating element embedded in an outer peripheral portion of the ceramic plate, and
the associated parts include a pair of terminals of the inner-peripheral-side resistance heating element and a pair of terminals of the outer-peripheral-side resistance heating element.

4. The ceramic heater according to claim 1, wherein the ceramic plate includes a body portion having a disk shape, having the wafer placement surface, and including the resistance heating element embedded therein, and an annular portion being concentric to the body portion and bonded to a rear surface of the body portion,
the recess is an inner center space of the annular portion; and
the elongate hole is formed by an elongate groove formed in a surface of the annular portion and the body portion.

5. The ceramic heater according to claim 1, wherein the ceramic plate includes a body portion having a disk shape, having the wafer placement surface, and including the resistance heating element embedded therein, and an annular portion being concentric to the body portion and bonded to a rear surface of the body portion,
the recess includes an inner center space of the annular portion and a circular hollow formed in a region of the rear surface of the body portion, the region being opposite to the inner center space of the annular portion; and
the elongate hole is formed by an elongate groove formed in the rear surface of the body portion to be communicated with the circular hollow and the annular portion.

6. The ceramic heater according to claim 1, wherein the side surface of the recess is located at a position visually recognizable from an end portion side of the tubular shaft.

7. The ceramic heater according to claim 1, wherein the elongate hole is a thermocouple-insertion elongate hole into which a thermocouple is to be inserted.

8. The ceramic heater according to claim 7, further comprising the thermocouple having been inserted into the elongate hole.

9. The ceramic heater according to claim 8, wherein the thermocouple has a shape following an inner wall of the tubular shaft in an inner space of the tubular shaft.

10. The ceramic heater according to claim 8, further comprising a thermocouple guide that guides a tip end of the thermocouple to pass through the opening of the elongate hole,
wherein the thermocouple is inserted into the elongate hole while being guided by the thermocouple guide.

11. The ceramic heater according to claim 10, wherein the thermocouple guide has a shape following an inner wall of the tubular shaft.

12. The ceramic heater according to claim 10, wherein the elongate hole includes a large-diameter portion and a small-diameter portion,
the large-diameter portion is a portion having a predetermined length from the opening, and the small-diameter portion is a portion of the elongate hole except for the large-diameter portion, and
large-diameter portion has a diameter allowing the tip end of the thermocouple guide to be inserted therethrough, and a diameter of the small-diameter portion is smaller than the diameter of the large-diameter portion and allows the thermocouple to be inserted therethrough.

13. A manufacturing method for a ceramic heater, comprising steps of:
(a) obtaining a ceramic plate by preparing a circular plate in which a resistance heating element is embedded and an annular plate having same outer diameter as the circular plate, by forming, on one surface of the annular plate, an elongate groove that extends from a center hole to an outer peripheral portion of the annular plate, and by bonding the circular plate to a surface of the annular plate on which the elongate groove has been formed;
(b) bonding a tubular shaft to a region of a rear surface of the ceramic plate around a recess that is formed by the center hole of the annular plate and the circular plate;
(c) boring a bottom surface of the recess in the ceramic plate to make the resistance heating element exposed at the bottom surface of the recess;
(d) bonding power feeder rods to the resistance heating element that has been exposed at the bottom surface of the recess; and
(e) inserting, with aid of the thermocouple guide, a thermocouple into an elongate hole that is formed by the elongate groove in the annular plate and the circular plate.
